(19) United States
(12) Patent Application Publication
(10) Pub. No.: US 2011/0147855 A1
(43) Pub. Date: Jun. 23, 2011

(54) DUAL SILICIDE FLOW FOR CMOS

(76) Inventors: Subhash M. Joshi, Hillsboro, OR (US); Chris Auth, Portland, OR (US)

(21) Appl. No.: 12/646,668

(22) Filed: Dec. 23, 2009

(51) Int. Cl. H01L 27/088; H01L 21/285

(52) U.S. Cl. 257/384; 438/682; 438/683; 257/E21.165; 257/E21.168; 257/E27.06

(57) ABSTRACT

A method for forming a semiconductor device decouples NMOS and PMOS silicide processing and thereby allows independent optimization of at least one characteristic of both NMOS and PMOS devices, and eliminates constraints of using the same silicide process for both NMOS and PMOS, which limits the degree to which the process can be optimized for either technology.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIGS. 1A-1G respectively depict cross-sectional views of a portion of an exemplary embodiment of a semiconductor device fabricated according to the subject matter disclosed herein; and

FIG. 2 depicts a flow diagram of an exemplary embodiment of a process of fabricating a semiconductor device according to the subject matter disclosed herein.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of exemplary techniques for optimizing implantation, silicide metal and anneal temperatures independently for the respective NMOS and PMOS devices of a device comprising both NMOS and PMOS devices are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. The word “exemplary” is used herein to mean “serving as an example, instance, or illustration.” Any embodiment described herein as “exemplary” is not to be construed as necessarily preferred or advantageous over other embodiments.

The subject matter disclosed herein relates to a technique that provides different pre-amorphization and silicide conditions for NMOS and PMOS devices. More specifically, the subject matter disclosed herein provides a technique that includes additional patterning steps to selectively implant or silicide only NMOS or only PMOS of a device comprising both NMOS and PMOS technologies, thereby optimizing implantation, silicide metal and anneal temperatures independently for the respective NMOS and PMOS devices.

NMOS and PMOS transistors generally have different requirements for silicide processes in terms of the optimum silicide metal work-function for best performance and in terms of pre-amorphization/anneal treatments for best uniformity and yield. One exemplary aspect of the subject matter disclosed herein decouples NMOS and PMOS silicide processing and thereby allows independent optimization of at least one characteristic of both NMOS and PMOS devices. Another exemplary aspect of the subject matter disclosed herein eliminates constraints of using the same silicide process for both NMOS and PMOS, which limits the degree to which the process can be optimized for either technology. These characteristics can include, but are not limited to, thickness, shape, composition, work function and microstructure of the silicide, which can be optimized by, but is not limited to, appropriate choice of pre-amorphization implants, dopant implants, silicide metal thickness, silicide metal composition, silicide formation anneal temperatures and process times.

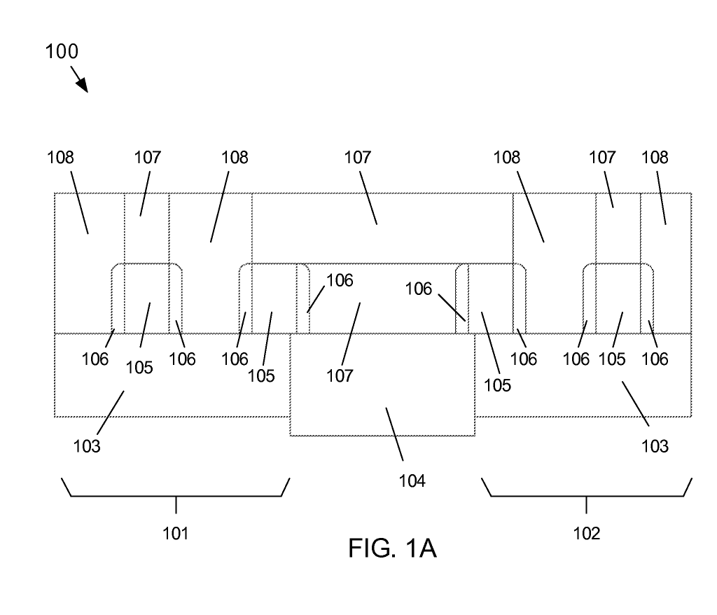

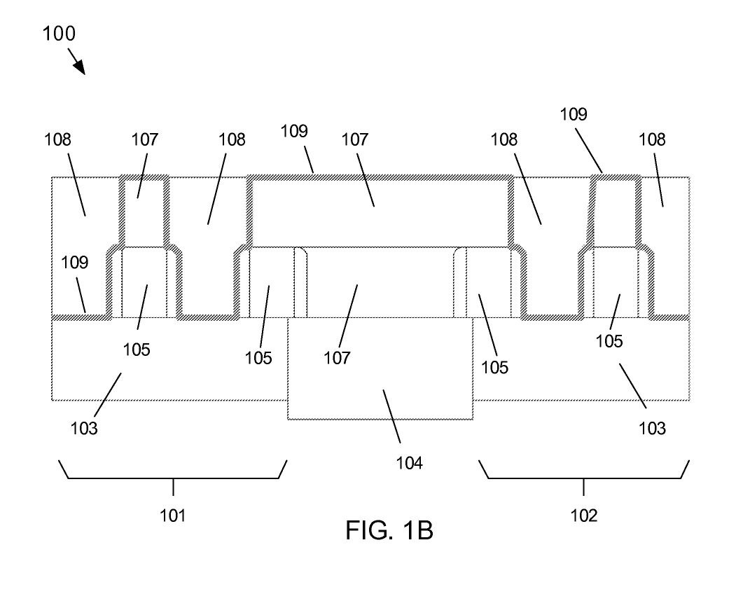

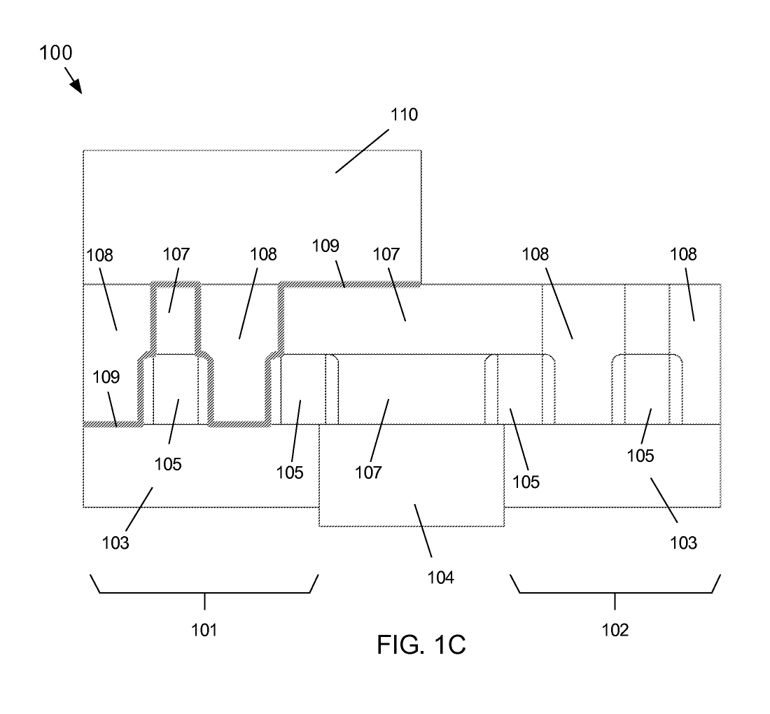

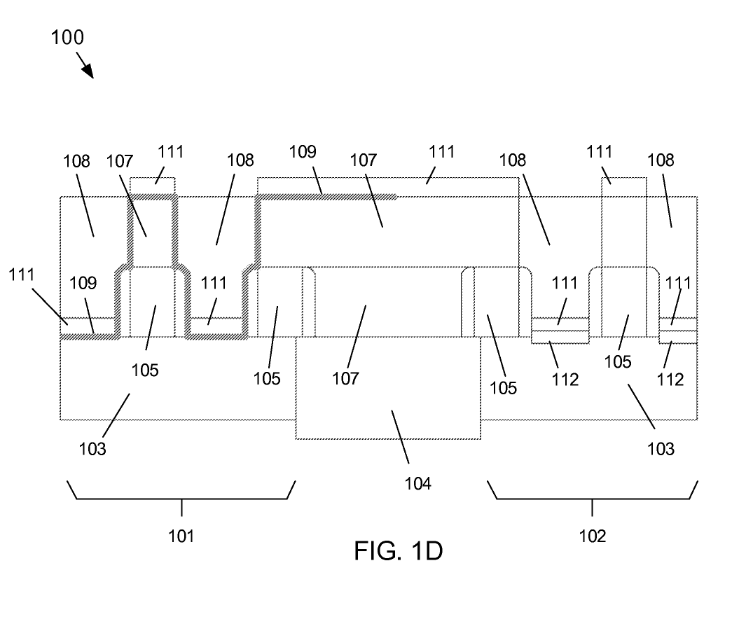

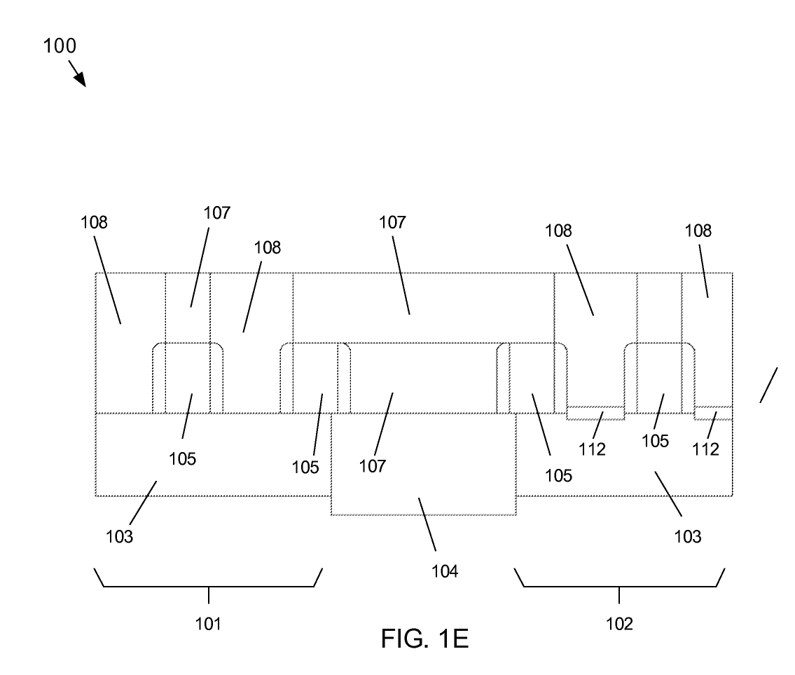

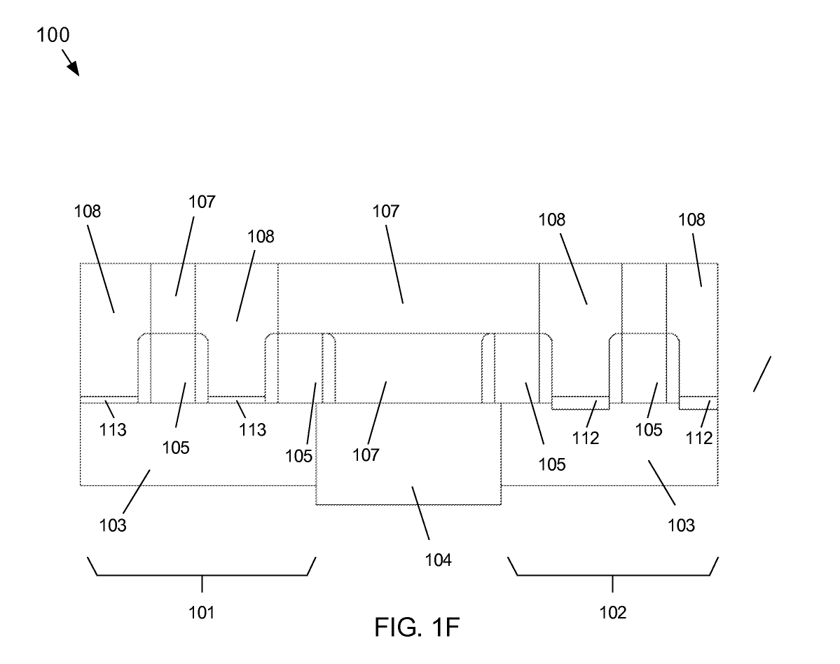

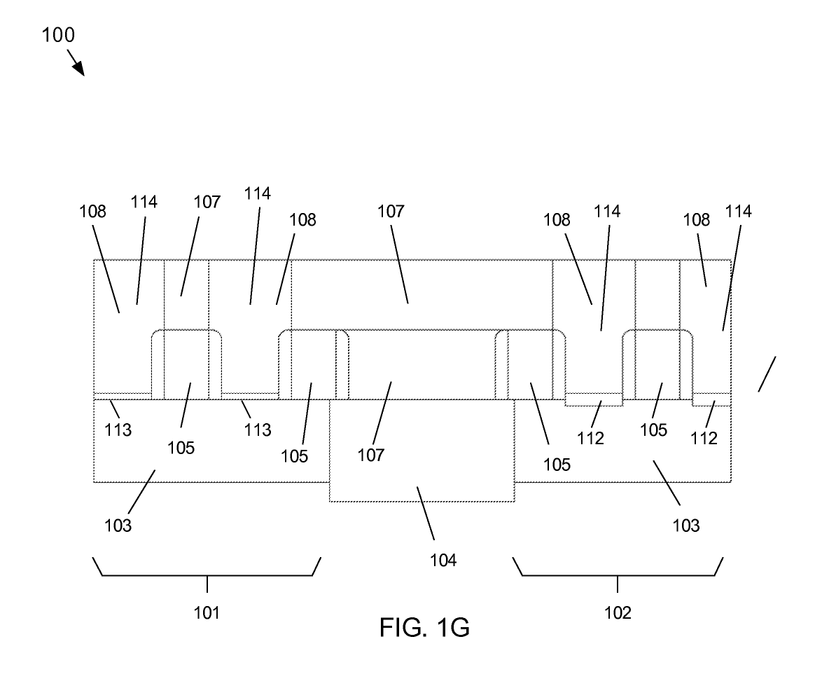

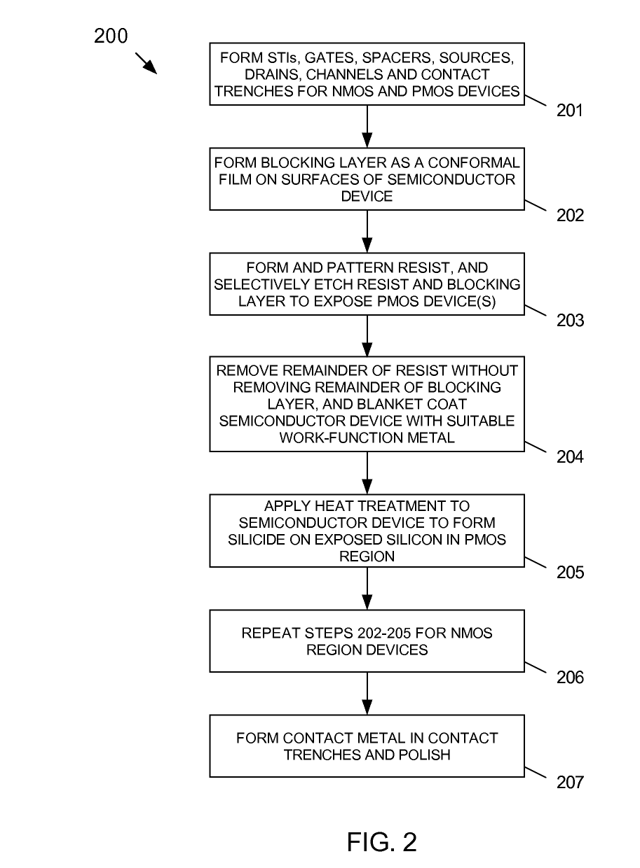

FIGS. 1A-1G respectively depict cross-sectional views of a portion of an exemplary to embodiment of a semiconductor device fabricated according to the subject matter disclosed herein. FIG. 2 depicts a flow diagram of an exemplary embodiment of a process 200 of fabricating a semiconductor device according to the subject matter disclosed herein.

FIG. 1A depicts a cross-section view of a portion of an exemplary embodiment of a partially fabricated semiconductor device 100 comprising an NMOS region 101 and a PMOS region 102. Semiconductor device 100 can comprise a substrate 103 formed from, but not limited to, silicon, and a shallow trench isolation (STI) region 104, of which only one STI region is shown. In one exemplary embodiment, the portion of substrate 103 comprises planar-geometry transistor structures, such as sources and drains that are not shown or indicated. In another exemplary embodiment, the portion of substrate 103 shown is a fin comprising source and drain regions that are not indicated. The portion of the exemplary embodiment of semiconductor device 100 also comprises gates 105, spacers 106 and oxide layers 107, which have been formed in a well-known manner. At this stage of fabrication, contact trenches 108 have been formed in a well-known manner that extend down to the surface of substrate (or fin) 103. Step 201 in FIG. 2 represents this stage of fabrication.

In FIG. 1B, a blocking, or masking, layer 109 is formed to be a conformal film on the surfaces of the semiconductor device 100, including the side and bottoms of contact trenches 108 and the top surfaces of oxide 107. Blocking layer 109 comprises an oxide, a nitride, or a combination thereof, and is formed in a well-known manner, such as by an atomic layer deposition (ALD) technique or a chemical vapor deposition (CVD) technique, or a combination thereof. It should be understood that not all of the structure shown in FIG. 1B is identified by a reference numeral for clarity. Step 202 in FIG. 2 represents this stage of fabrication.

After blocking layer 109, is formed, a resist coating 110, such as, but not limited to, a photoresist, is formed on blocking layer 109 in a well-known manner. Next, resist coating 110 is patterned and etched in a well-known manner, such as by either a wet or a dry etch. A portion of blocking layer 109 is also removed during etching. For this example, a portion of blocking layer 109 covering PMOS region 102 is removed leaving the side and bottoms of contact trenches 108 in PMOS region 102 and the top surfaces of oxide 107 exposed. FIG. 1C depicts a cross-section view of a portion of the exemplary embodiment of partially fabricated semiconductor device 100 after resist coating 110 and a portion of blocking layer 109 have been removed. Step 203 in FIG. 2 represents this stage of fabrication. While the exemplary embodiment described exposes PMOS region 102 first, it should be understood that in an exemplary alternative embodiment, NMOS region 101 could be patterned and exposed first.

The remainder of resist 110 is then removed from semiconductor device 100 using a well-known wet or dry etch technique leaving blocking layer 109 still covering NMOS portion 101. A suitable silicide metal 111 for a PMOS device, such as, but not limited to, tungsten, titanium, cobalt, nickel, platinum, or palladium or combinations thereof, is then blanket deposited on semiconductor device 100 using a well-known physical vapor deposition (PVD) technique. Alternatively or additionally, the exposed devices in PMOS region 102 could be selectively implanted with ions in a well-known manner, with species suitable for a PMOS device such as, but not limited to, silicon, germanium, carbon, nitrogen, boron, indium, aluminum, gallium, sulphur, selenium, erbium, yttrium, ytterbium, hydrogen, fluorine, deuterium or combinations thereof. Step 204 in FIG. 2 represents this stage of fabrication. A well-known heat treatment is then applied to device 100 to form a silicide 112 wherever metal 111 is in direct contact with silicon in PMOS region 102. In NMOS region 101, where blocking layer 109 to prevents metal 111 from contacting silicon, no silicide is formed. Step 205 in FIG. 2 represents this stage of fabrication. FIG. 1D depicts a cross-section view of a portion of the exemplary embodiment of partially fabricated semiconductor device 100 after silicide metal 111 has been blanket coated on device 100 and device 100 has been heat treated to form silicides in PMOS region 102.

Excess silicide metal 111 is removed in a well-known manner. Additionally, the remainder of blocking layer 109 is removed in a well-known manner. FIG. 1E depicts a cross-section view of a portion of the exemplary embodiment of partially fabricated semiconductor device 100 after silicide metal 111 and the remainder of blocking layer 109 have been removed.

At this point, the process depicted in FIGS. 1B through 1E is repeated, except that this time a suitable silicide metal for an NMOS device will be deposited in order to form a suitable silicide for NMOS region 101. Step 206 in FIG. 2 represents this stage of fabrication in which the process is repeated for NMOS devices in NMOS region 101. Referring to FIG. 1B, a blocking, or masking, layer 109 is formed to be a conformal film on the surfaces of the semiconductor device 100, including the side and bottoms of contact trenches 108 and the top surfaces of oxide 107. Blocking layer 109 again comprises an oxide, a nitride, or a combination thereof, and is formed in a well-known manner, such as by an atomic layer deposition (ALD) technique or a chemical vapor deposition (CVD) technique, or a combination thereof. Referring to FIG. 1C, a resist coating is been formed on blocking layer 109 in a well-known manner. The resist coating is patterned and etched in a well-known manner, such as by either a wet or a dry etch, except that this time, the patterning and etching exposes NMOS region 101. A portion of blocking layer 109 is also removed during etching so that the side and bottoms of contact trenches 108 in NMOS region 101 and the top surfaces of oxide 107 are exposed.

Referring to FIG. 1D, the remainder of the resist is then removed from semiconductor device 100 using a well-known wet or dry etch technique leaving blocking layer 109 still covering PMOS portion 102. A suitable silicide metal for an NMOS device, such as, but not limited to, tungsten, titanium, cobalt, nickel, aluminum, yttrium, erbium, or ytterbium, or combinations thereof, is then blanket deposited on semiconductor device 100 using a well-known physical vapor deposition (PVD) technique. Alternatively or additionally, the exposed devices in NMOS region 101 could be selectively implanted with ions in a well-known manner, with species suitable for a NMOS device such as, but not limited to, silicon, germanium, carbon, nitrogen, phosphorus, arsenic, antimony, sulphur, selenium, erbium, yttrium, ytterbium, hydrogen, fluorine, deuterium or combinations thereof.

A well-known heat treatment is then applied to device 100 to form a silicide 113 (FIG. 1F) wherever the suitable silicide metal for an NMOS device is in direct contact with silicon in NMOS region 101. In PMOS region 102, where silicide layer 112 prevents the suitable silicide metal for an NMOS device from contacting silicon, no additional silicide is formed. Referring to FIG. 1E, the excess silicide metal for an NMOS device is removed in a well-known manner. Additionally, the remainder of blocking layer 109 is removed in a well-known manner. FIG. 1F depicts a cross-section view of a portion of the exemplary embodiment of partially fabricated semiconductor device 100 after a silicide metal suitable for an NMOS device and the remainder of the blocking layer have been removed.

After both PMOS silicide 112 and NMOS silicide 113 have been formed, contact fill metal 114 is filled in contact trenches 108 in a well-known manner. Suitable contact metals include, but are not limited to, titanium, tantalum, tungsten, copper, aluminum, silver, or gold, or combinations thereof. A well-known polishing technique is then performed to complete to semiconductor device 100. It should be understood that additional steps may be performed that have not been described herein. It should also be understood that in an exemplary alternative embodiment, the silicide for an NMOS device is formed prior to the silicide for a PMOS device. FIG. 1G depicts a cross-section view of a portion of the exemplary embodiment of partially fabricated semiconductor device 100 after contact metal has been formed in the contact trenches and polished. Step 207 in FIG. 2 represents this stage of fabrication.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A method for forming a semiconductor device, comprising:
covering a substrate of the semiconductor device with a first barrier layer, the substrate comprising a region of at least one NMOS device and a region of at least one PMOS device, the region of the at least one NMOS device and the region of the at least one PMOS device each comprising at least one contact trench that exposes a surface of the substrate, the first barrier layer covering at least a portion of the region of the at least one NMOS device and at least a portion of the region of the at least one PMOS device and the at least one contact trench in each region covered by the barrier layer;
selectively removing the first barrier layer from the region of the at least one NMOS device or the region of the at least one PMOS device to expose the at least one contact trench in the region from which the first barrier layer was removed;
coating the region of at least one NMOS device and the region of the at least one PMOS device with a first silicide metal so that the first silicide metal covers a bottom of the at least one contact trench in the region from which the first barrier layer was removed;
heat treating the substrate to form a first silicide on the surface of the substrate exposed by the bottom of the at least one contact trench when the first barrier layer was removed;
removing excess first silicide metal used to form the silicide in the region from which the first barrier layer was removed;
covering the substrate with a second barrier layer, the second barrier layer covering at least a portion of the region of the at least one NMOS device and at least a portion of the region of the at least one PMOS device and the at least one contact trench in each region covered by the barrier layer;
selectively removing the second barrier layer from the region of the at least one NMOS device or the region of the at least one PMOS device that was not exposed when the first barrier layer was removed to expose the contact trenches in the region from which the second barrier layer was removed;
coating the region of the at least one NMOS device and the region of the at least one PMOS device with a second silicide metal so that the second silicide metal covers a bottom of the at least one contact trench in the region from which the second barrier layer was removed; and
heat treating the wafer to form a second silicide on the surface of the substrate exposed by the bottom of the at least one contact trench when the second barrier layer was removed.

2. The method according to claim 1, further comprising:
removing excess second silicide metal used to form the second silicide in the region from which the second barrier layer was removed; and
forming a contact metal in at least one contact trench.

3. The method according to claim 2, wherein the first silicide metal used for forming the first silicide in the region of the at least one NMOS device comprises tungsten, titanium, cobalt, nickel, aluminum, yttrium, erbium, or ytterbium, or combinations thereof.

4. The method according to claim 2, wherein the second silicide metal used for forming the second silicide in the region of the at least one PMOS device comprises tungsten, titanium, cobalt, nickel, platinum, or palladium, or combinations thereof.

5. The method according to claim 4, wherein the first silicide metal used for forming the first silicide in the region of the at least one NMOS device comprises tungsten, titanium, cobalt, nickel, aluminum, yttrium, erbium, or ytterbium, or combinations thereof.

6. The method according to claim 5, wherein the second silicide metal used for forming the second silicide in the region of the at least one PMOS device is selected to optimize at least one characteristic of the at least one PMOS device, and
wherein the first silicide metal used for forming the first silicide in the region of the at least one NMOS device is selected to optimize at least one characteristic of the at least one NMOS device.

7. The method according to claim 6, wherein the at least one characteristic optimized for the at least one PMOS device comprises a thickness, a shape, a composition, a work function and a microstructure of the second silicide, or combinations thereof, and
wherein the at least one characteristic optimized for the at least one NMOS device comprises a thickness, a shape, a composition, a work function and a microstructure of the first silicide, or combinations thereof.

8. The method according to claim 7, wherein the first barrier layer is removed from the region of the at least one PMOS device, and
wherein the second barrier layer is removed from the region of the at least one NMOS device.

9. The method according to claim 7, wherein the first barrier layer is removed from the region of the at least one NMOS device, and
wherein the second barrier layer is removed from the region of the at least one PMOS device.

10. A semiconductor device, comprising:
a substrate comprising a region of at least one NMOS device and a region of at least one PMOS device, the region of the at least one NMOS device and the region of the at least one PMOS device each comprising at least one contact trench that exposes a surface of the substrate; and
a first silicide formed on a surface of the substrate in the at least one contact trench in the region of the at least one NMOS device being optimized for a characteristic of at least one NMOS device, and a second silicide formed on a surface of the substrate in the at least one contact trench in the region of the at least one PMOS device being optimized for a characteristic of at least one PMOS device, the first silicide being formed from a first silicide metal and the second silicide being formed from a second silicide metal.

11. The semiconductor device according to claim 10, wherein the first silicide metal used for forming the first silicide in the region of the at least one NMOS device comprises tungsten, titanium, cobalt, nickel, aluminum, yttrium, erbium, or ytterbium, or combinations thereof.

12. The semiconductor device according to claim 10, wherein the second silicide metal used for forming the second silicide in the region of the at least one PMOS device comprises tungsten, titanium, cobalt, nickel, platinum, or palladium, or combinations thereof.

13. The semiconductor device according to claim 12, wherein the first silicide metal used for forming the first silicide in the region of the at least one NMOS device comprises tungsten, titanium, cobalt, nickel, aluminum, yttrium, erbium, or ytterbium, or combinations thereof.

14. The semiconductor device according to claim 13, wherein the second silicide metal used for forming the second silicide in the region of the at least one PMOS device is selected to optimize at least one characteristic of the at least one PMOS device, and
wherein the first silicide metal used for forming the first silicide in the region of the at least one NMOS device is selected to optimize at least one characteristic of the at least one NMOS device.

15. The semiconductor device according to claim 14, wherein the at least one characteristic optimized for the at least one PMOS device comprises a thickness, a shape, a composition, a work function and a microstructure of the silicide, or combinations thereof, and
wherein the at least one characteristic optimized for the at least one NMOS device comprises a thickness, a shape, a composition, a work function and a microstructure of the silicide, or combinations thereof.

16. The semiconductor device according to claim 15, wherein the first and second silicides are formed by:
covering the region of the at least one NMOS device and the region of the at least one PMOS device with a first barrier layer, the first barrier layer covering at least a portion of the region of the at least one NMOS device and at least a portion of the region of the at least one PMOS device and the at least one contact trench in each region covered by the barrier layer;
selectively removing the first barrier layer from the region of the at least one NMOS device to expose the at least one contact trench in the region from which the first barrier layer was removed;
coating the region of at least one NMOS device with the first silicide metal so that the first silicide metal covers a bottom of the at least one contact trench in the region from which the first barrier layer was removed;
heat treating the substrate to form the first silicide on the surface of the substrate exposed by the bottom of the at least one contact trench when the first barrier layer was removed;
removing excess first silicide metal used to form a first silicide in the region from which the first barrier layer was removed;
covering the substrate with a second barrier layer, the second barrier layer covering at least a portion of the region of the at least one NMOS device and at least a portion of the region of the at least one PMOS device and the at least one contact trench in each region covered by the barrier layer;
selectively removing the second barrier layer from the region of the at least one PMOS device that was not exposed when the first barrier layer was removed to expose the contact trenches in the region from which the second barrier layer was removed;
coating the region of the at least one NMOS device and the region of the at least one PMOS device with a second silicide metal so that the second silicide metal covers a bottom of the at least one contact trench in the region from which the second barrier layer was removed; and
heat treating the wafer to form the second silicide on the surface of the substrate exposed by the bottom of the at least one contact trench when the second barrier layer was removed.

17. The semiconductor device according to claim 16, wherein the first and second silicides are further formed by:
removing excess second silicide metal used to form the second silicide in the region from which the second barrier layer was removed; and
forming a contact metal in at least one contact trench.

18. The semiconductor device according to claim 15, wherein the first and second silicides are formed by:
covering the region of the at least one NMOS device and the region of the at least one PMOS device with a first barrier layer, the first barrier layer covering at least a portion of the region of the at least one NMOS device and at least a portion of the region of the at least one PMOS device and the at least one contact trench in each region covered by the barrier layer;
selectively removing the first barrier layer from the region of the at least one PMOS device to expose the at least one contact trench in the region from which the first barrier layer was removed;
coating the region of at least one PMOS device with the second silicide metal so that the second silicide metal covers a bottom of the at least one contact trench in the region from which the first barrier layer was removed;
heat treating the substrate to form the second silicide on the surface of the substrate exposed by the bottom of the at least one contact trench when the first barrier layer was removed;
removing excess second silicide metal used to form a second silicide in the region from which the first barrier layer was removed;
covering the substrate with a second barrier layer, the second barrier layer covering at least a portion of the region of the at least one NMOS device and at least a portion of the region of the at least one PMOS device and the at least one contact trench in each region covered by the barrier layer;
selectively removing the second barrier layer from the region of the at least one NMOS device that was not exposed when the first barrier layer was removed to expose the contact trenches in the region from which the second barrier layer was removed;
coating the region of the at least one NMOS device and the region of the at least one PMOS device with a first silicide metal so that the first silicide metal covers a bottom of the at least one contact trench in the region from which the second barrier layer was removed; and
heat treating the wafer to form the first silicide on the surface of the substrate exposed by the bottom of the at least one contact trench when the second barrier layer was removed.

19. The semiconductor device according to claim 18, wherein the first and second silicides are further formed by:
removing excess first silicide metal used to form the first silicide in the region from which the second barrier layer was removed; and
forming a contact metal in at least one contact trench.
